(19) United States
(12) Patent Application Publication
(10) Pub. No.: US 2022/0311206 A1
(43) Pub. Date: Sep. 29, 2022

(54) SEMICONDUCTOR LASER DEVICE STRUCTURES AND METHODS OF FABRICATION THEREOF

(71) Applicant: ElectroPhotonic-IC Inc., Kanata (CA)

(72) Inventors: Richard D. CLAYTON, Ottawa (CA); William A. HAGLEY, Ottawa (CA); Lawrence E. TAROF, Kanata (CA)

(21) Appl. No.: 17/641,968

(22) PCT Filed: Oct. 5, 2020
(86) PCT No.: PCT/CA2020/051334

§ 371 Date: Mar. 10, 2022

Related U.S. Application Data
(60) Provisional application No. 62/912,148, filed on Oct. 8, 2019.

(51) Int. Cl. H01S 5/028; H01S 5/10; H01S 5/125; H01S 5/026

(52) U.S. Cl. CPC H01S 5/0287; H01S 5/1082; H01S 5/125; H01S 5/0264; H01S 2301/166

(57) ABSTRACT

Semiconductor device structures comprising laser diode cavities with at least one of a mode-selective filter and a phase-alignment element, and methods for their fabrication, are disclosed. An example device structure comprises a surface-etched grating distributed-feedback (SEG DFB) laser with a mode-selective reflector structure. The reflector structure is designed to provide higher pot feedback of the fundamental TE0 mode and suppression of higher order mode effects. The reflector structure may be a single interface (single facet) mirror type reflector comprising a spatially patterned reflector, or a multi-interface distributed Bragg reflector (DBR). A phase alignment element may be included to provide precise optical phase control. A photodetector for back-facet power monitoring may be included. A method of fabrication is disclosed, based on a self-aligned process in which DBR features are included on the same mask that is used for the DFB laser grating.

### CROSS-REFERENCE TO RELATED APPLICATION(S)

This application claims priority from U.S. provisional patent application No. 62/912,148, filed Oct. 8, 2019, entitled “Semiconductor Laser Device Structures and Methods of Fabrication thereof”, which is incorporated herein by reference in its entirety.

### TECHNICAL FIELD

The present invention relates to semiconductor device structures comprising laser diodes and methods for their fabrication, and more particularly to surface-etched grating (SEG) distributed feedback (DFB) lasers and methods for their fabrication.

### BACKGROUND

US2012/0106583 published May 3, 2012 (Watson et al.), entitled “Vertically-Coupled Surface-Etched-Grating DFB laser”, discloses a laser diode structure having a vertically coupled (VC) surface-etched-grating (SEG). This device structure is compatible with single-growth monolithic integration for photonic integrated circuits (PIC) implemented with InP and related III-V semiconductor materials.

It has been demonstrated that VC SEG DFB lasers of the structure disclosed in US2012/0106583 can be fabricated to provide reliable, high volume, high yield, high performance DFB lasers for operation at >2.5 Gb/s when used with spot size converters. However, under some operating conditions, these lasers demonstrate unacceptable multi-transverse mode operation, particularly when operated without transition waveguides and spot size converters.

The VC SEG DFB laser structure has etched front and back facets. Typically, DFB lasers with etched facets use a high reflectivity coating on one facet and a lower reflectivity coating on the other facet to improve single mode yield. That is, the back-facet has a high reflectivity coating, such as a metal coating, e.g. gold, and the front facet has a lower reflectivity coating. The high reflectivity back facet reflector provides the feedback needed for consistent spectral and modulation characteristics. However, facet coating is expensive. A high reflectivity metal reflector on the back facet that blocks light entirely is not suitable if back-facet power monitoring (BPM) is required. That is, some leakage of light is required for BPM by a photodetector positioned behind the back-facet. Another issue is that any misalignment and phase variations between the teeth of the SEG and the reflective facets can lead to a reduced yield of lasers that meet acceptable performance requirements, with a corresponding increase in cost per acceptable die.

For many applications it is desirable to provide high performance laser diodes at lower cost. For example, electron-beam (e-beam) writing of grating structures tends to be expensive, and not as readily accessible as photolithography with stepper mask defined gratings. It is therefore desirable to provide device structures with surface-etched-gratings that can be defined by stepper mask photolithography. Thus, there is a need for further improvements to SEG DFB laser structures, e.g. to offer improved performance or lower cost manufacturing. In particular, there is a need for further improvements or alternative solutions to prevent, or at least reduce, higher order mode effects in SEG DFB lasers.

These types of issues, e.g., one or more of unacceptable multi-mode operation, misalignment and phase variations, yield and fabrication costs, are not confined to SEG DFB lasers. More generally, there is a need for improvements to address related performance and yield issues for other types of semiconductor laser structures.

### SUMMARY OF INVENTION

The present invention seeks to eliminate or mitigate one or more of the above-mentioned disadvantages of known device structures and methods of fabrication, or at least provide an alternative.

Aspects of the invention provide semiconductor devices structures comprising laser diodes comprising at least one of a mode-selective filter and a phase-alignment element, and methods for their fabrication.

In some embodiments, a semiconductor device structure comprises a laser diode cavity supporting multiple transverse modes, the laser diode cavity having at least one etched facet, wherein the at least one etched facet comprises a mode-selective structured reflector providing higher feedback of a selected mode order compared to other mode orders. The laser diode cavity may be any one of a FP, DFB and DBR laser cavity.

The structured reflector may be a single facet, spatially patterned reflector comprising one or more layers of: a dielectric, or a metal or a combination of metal and dielectric. For example, the selected mode is a fundamental TE0 mode and the spatially patterned reflector provides higher feedback of the fundamental TE0 mode; or the selected mode is a first order TE1 mode and the spatially patterned reflector provides higher feedback of the TE1 mode relative to other modes.

The at least one etched facet may be an element of a periodic multi-surface reflector. For example, the periodic multi-surface reflector is a DBR (Distributed Bragg Reflector).

In some embodiments the semiconductor device structure comprises a laser diode cavity supporting a single longitudinal mode, and either a single transverse mode or multiple transverse modes, and comprises feedback structures contributing to single longitudinal mode operation of the device and a phase alignment structure self-aligned to the feedback structures, the phase alignment structure defining the phase of the at least one etched facet relative to the feedback structures. For example, the feedback structures comprise grating structures, and the phase alignment structure is an etched/not etched region between the grating structures and the at least one etched facet. A detector for back-facet power monitoring may be included.

A semiconductor structure of other embodiments may comprise a laser diode cavity having any feasible combination of individual features disclosed herein.

An example of a method of patterning a plurality of phase-aligned etched structures on a semiconductor substrate comprises:

providing a substrate having a desired semiconductor layer structure;
depositing a primary etch mask;
patterning the primary etch-mask in a single high relative dimensional fidelity step to define phase-aligned patterns for each of the plurality of phase-aligned etched structures; and
processing the plurality of phase-aligned etched structures by a sequence of area selective masking and etching steps.

Processing may comprise: performing an etch to an initial etch depth through the primary etch mask to define an initial part of each of the plurality of phase-aligned etched structures. Processing may comprise: depositing a first area selective etch (SE) mask and patterning the first area SE mask to expose a first area of the primary etch mask defining at least one of the plurality of phase-aligned etched structures and to protect other areas of the primary etch mask; performing a first etch to a first etch depth into the semiconductor layer structure through the first area of the primary etch mask; and if required, removing the first area SE mask. Processing may comprise depositing a second area selective etch (SE) mask and patterning the second area SE mask to expose a second area of the primary etch mask defining at least one of the plurality of phase-aligned etched structures and to protect other areas of the primary etch mask; performing a second etch to a second etch depth into the semiconductor layer structure through the first area of the primary etch mask; and if required, removing the second area SE mask. When required, for n=3, the method further comprises depositing an n^{th} area selective etch (SE) mask and patterning the n^{th} area SE mask to expose n^{th} area of the primary etch mask defining at least one of the plurality of phase-aligned etched structures and protecting other areas of the primary etch mask; performing an n^{th} etch to an n^{th} etch depth into the semiconductor layer structure through the n^{th} area of the primary etch mask; if required, removing the n^{th} area SE mask; and if required, for n>3 repeating said masking and etching steps, until each of the plurality of phase-aligned etched structures is completed.

If required, the primary etch-mask is removed after completion of all of the plurality of phase-aligned etched structures.

In some embodiments described in detail, mode-selective SEG DFB lasers are provided comprising mode-selective filters in the form of structured reflectors. For example, designs are disclosed for InP semiconductor based VC SEG DFB lasers comprising mode-selective structured reflectors that provide higher feedback for the fundamental TE0 mode as compared to the higher-order transverse modes. The structured reflectors may comprise single interface mirror type reflectors or multi-interface distributed Bragg reflector (DBR) structures, and may include a phase-alignment structure.

This approach can allow relaxation of VC SEG laser cavity design and processing while providing for high performance operation with high yield of both single lateral mode and single longitudinal mode operation. Methods of fabrication of these structures are disclosed, which provide for at least one of higher-order mode suppression, improved phase-alignment, lower cost, improved reliability, et al.

In an exemplary embodiment a device structure comprises: a distributed feedback (DFB) laser diode including a surface-etched grating (SEG) supporting a fundamental optical mode (and potentially supporting additional transverse modes), the laser diode having etched front and back facets, wherein the back facet comprises a mode-selective structured reflector providing higher feedback of a fundamental mode TE0 compared to higher order modes.

Beneficially, the mode-selective structured reflector is a phase-aligned mode-selective reflector structure spaced from teeth of the SEG by a phase-alignment region.

In some embodiments, the mode-selective structured reflector comprises a single interface reflector comprising a spatially patterned reflective coating on the back-facet that provides said higher feedback of the fundamental mode TE0 relative to higher order modes. For example, the reflector structure is a phase-aligned reflector structure wherein the single interface reflector comprises an etched trench defining the back-facet, and the back-facet is spaced from teeth of the SEG by a phase-alignment region.

For example, a sidewall of the trench defines the back-facet and the spatially patterned reflective coating comprises a high reflectivity coating in a region aligned to the TE0 mode, e.g. a narrow vertical strip centered on the optical aperture, and a lower reflectivity coating on other parts of the trench sidewall. The etched trench is one of: a rectangular trench, a trapezoidal trench, a hexagonal trench, and trenches of other suitable geometric forms, including curved forms.

In other embodiments, the mode-selective structured reflector comprises a multi-interface distributed Bragg reflector (DBR) structure defined by a plurality of etched and un-etched regions defining a series of trenches laterally aligned to the back-facet, sidewalls of said trenches of the DBR structure comprising a dielectric coating that provides said higher feedback of the fundamental mode TE0 relative to higher order modes. Beneficially, the DBR structure is a phase-aligned DBR reflector structure spaced from teeth of the SEG by a phase-alignment region. The etched trenches of the DBR structure have a geometric form which is one of a rectangular trench, a trapezoidal trench, a hexagonal trench, and trenches of other suitable geometric forms.

For example, in one embodiment, the etched and unetched regions of the DBR structure comprise a plurality of (2m+1)*λ/4 etched and not-etched sections, comprising 1 to 3 periods, where m=1 for low index (etched) regions, e.g. air and other sufficiently low index materials, and m=2 for high index (unetched) regions, i.e. semiconductor materials. The choices of ‘m’ may be made, for example, to make the dimensions of the relevant structures suitable for well controlled processing.

The device structure may further comprise a detector for back-facet power monitoring.

In an exemplary embodiment, a VC SEG DFB laser structure is fabricated from a epitaxial layer structure comprising a plurality of semiconductor layers grown on a semiconductor substrate, e.g. a InP substrate and InP based III-V semiconductor materials. The plurality of semiconductor layers comprise a first contact layer, a first cladding layer, a first separate confinement heterostructure, a multi-quantum well active gain region, an second separate confinement heterostructure, and a second cladding layer and a second contact layer. The surface-etched grating (SEG) comprises a set of periodic trenches defined along a top surface of a mesa which is formed by etching through the plurality of semiconductor layers, the SEG forming a vertically coupled waveguide Bragg grating supporting a fundamental optical mode. The separate confinement heterostructures provide vertical optical confinement of the fundamental optical mode. At least one layer of the plurality of semiconductor layers forms an aperture layer that provides lateral optical confinement of the fundamental optical mode and lateral confinement of current injection. Etched regions of the DBR structure are etched through at least upper layers of said plurality of semiconductor layers, e.g. to the first cladding layer.

In an exemplary embodiment, a method of fabricating a device structure comprising a SEG DFB laser and a phase-aligned mode-selective reflector structure, comprises: providing a substrate comprising an epitaxial layer structure for the SEG DFB laser;

depositing and patterning a phase-aligned (PA) etch mask layer defining all features for etching the SEG for the DFB laser, a phase-alignment region, and a mode-selective reflector structure;
performing a first etch to a first etch depth to define the SEG and define etched/not-etched regions for the phase-alignment region and the mode-selective reflector structure;
depositing and patterning an area selective (i.e. spatially selective) etch (SE) mask layer which protects the SEG and exposes regions of the phase-alignment region and the mode-selective reflector structure;
performing a second etch to a second etch depth to define features of the phase-alignment region and the mode-selective reflector structure.

The method may further comprise depositing and patterning at least one additional area selective etch (SE) mask layer; and performing another etch to a third or subsequent etch depth to further define the features of the phase-alignment region and the mode-selective reflector structure.

In a method of one embodiment, the phase-aligned mask layer defines etched and un-etched regions for a mode-selective reflector comprising a trench for a single interface back facet reflector; and comprises depositing a spatially patterned reflective coating on a sidewall of the trench defining the back-facet of the SEG DFB laser, the spatially patterned reflective coating comprising a first region of a high reflectivity coating that provides higher feedback to a fundamental TE0 mode relative to higher order modes of the SEG DFB laser, and other regions having a lower reflectivity coating.

In a method of another embodiment the phase-aligned mask layer defines etched and un-etched regions for a mode-selective reflector comprising a series of trenches of a mode-selective DBR structure; and comprises depositing a dielectric coating on a sidewalls of the series of trenches to form a DBR structure that provides higher feedback to a fundamental TE0 mode relative to higher order modes of the SEG DFB laser.

In a method of another embodiment, all phase-aligned etches are done independently through separate mask and etch steps.

If required, the phase-aligned mask layer further defines a detector for back-facet monitoring. In variants of the method, the first etch defining the SEG is performed after the second etch forming the phase-alignment region and mode-selective reflector structure, i.e. the SEG region is protected while other features are etched.

In some embodiments, the phase alignment region may be omitted, and thus the steps for fabrication of the phase alignment region are omitted from the method.

In some embodiments, a VC SEG DFB laser is provided wherein, instead of forming the aperture layer by a lateral undercut or etch, the aperture is formed by a process such as ion implantation or chemical processing of an aperture layer, to modify the structure and composition of the aperture layer (e.g. modification of the lateral profile of refractive index) to form the aperture which provides lateral confinement of the current injection and lateral confinement of the optical mode, and/or the aperture may be formed by one or more other layers of the mesa, i.e. not positioned at the bottom of the mesa.

In some embodiments, a VC SEG DFB laser is provided wherein, a metal layer is provided on a top surface of the mesa and patterned to form an etch mask for the SEG. That is, a layer of conductive metal that forms at least part of the top contact for the laser may be extended to provide the etch mask for at least the SEG grating structure. Thus, this conductive layer extends across the grating teeth. The resulting top contact structure provides improved ohmic placement for current flow through the active region.

The foregoing and other objects, features, aspects and advantages of the present invention will become more apparent from the following detailed description, taken in conjunction with the accompanying drawings, of example embodiments of the invention, which description is by way of example only.

### BRIEF DESCRIPTION OF THE DRAWINGS

FIG. 1A (Prior art) is a schematic isometric diagram of an example of a laterally-coupled (LC) SEG DFB laser integrated with a rear facet power monitor and a vertical mode transition to couple the laser output to a passive waveguide;

FIG. 1B (Prior art) is an enlarged schematic isometric diagram the LC SEG DFB laser of FIG. 1A;

FIG. 2 (Prior art) is a schematic isometric diagram of a vertically-coupled (VC) SEG DFB laser;

FIG. 3 (Prior art) is a schematic cross-sectional view of the mesa structure of the VC SEG DFB laser of FIG. 2;

FIG. 4 (Prior Art) shows a schematic cross-sectional diagram illustrating the layer structure of the VC SEG DFB laser of FIG. 3 with contour lines showing a two-dimensional profile for the mode pattern of the fundamental guided mode;

FIG. 5 shows mode patterns for each of the TE0, TE1 and TE2 modes for DFB laser device structures of embodiments having a 1 μm aperture and a 2 μm aperture, to illustrate the mode overlap region;

FIG. 6A is a schematic diagram of a device structure comprising a VC SEG DFB laser with a phase-aligned mode-selective reflector of a first embodiment comprising a single interface mirror structure;

FIG. 6B is a schematic diagram of a device structure comprising a VC SEG DFB laser with a phase-aligned mode-selective reflector of a second embodiment comprising a single interface mirror structure;

FIG. 6C is a schematic diagram to illustrate some alternative forms (a) and (b) of trenches for device structures which are variants of those shown in FIGS. 6A and 6B;

FIG. 7A is a schematic diagram of a device structure comprising a VC SEG DFB laser with a phased aligned mode-selective reflector of a third embodiment comprising a multi-interface DBR type structure;

FIG. 7B is a schematic diagram of a device structure comprising a VC SEG DFB laser with a phased aligned mode-selective reflector of a fourth embodiment comprising a multi-interface DBR type structure;

FIG. 7C is a schematic diagram of a device structure comprising a VC SEG DFB laser with a phased aligned mode-selective reflector of a fifth embodiment comprising a waveguide type (dielectric) lateral DBR structure;

FIG. 7D is a schematic diagram of a device structure comprising a VC SEG DFB laser with a phased aligned mode-selective reflector of a sixth embodiment comprising a waveguide type (metallic) lateral DBR type structure;

FIG. 8A shows some schematic cross-sectional diagrams to illustrate some alternative forms of DBR trenches, labelled Type 1, Type 2a and Type 2b, for device structures which are variants of those shown in FIGS. 7A and 7B;

FIG. 8B is a schematic diagram of a cross-sectional view through part of the SEG and an etched reflector trench;

FIG. 9 is a schematic diagram to show an example of an epitaxial layer structure for a device comprising a VC SEG DFB laser and structured reflector of an exemplary embodiment;

FIG. 10 shows an SEM image of an example of a VC SEG DFB laser structure to show the form of the mesa structure with an aperture layer;

FIG. 11 shows a series of schematic diagrams to illustrate steps A. to G. in a process for fabricating a laser structure comprising phase-aligned laser reflectors (process variant A with DBR and BFM);

FIG. 12 shows a schematic cross-sectional view of the mesa structure of a VC SEG DFB laser of another embodiment; and

FIG. 13 shows a schematic diagram of a VC SEG DFB laser yet another embodiment.

### DETAILED DESCRIPTION

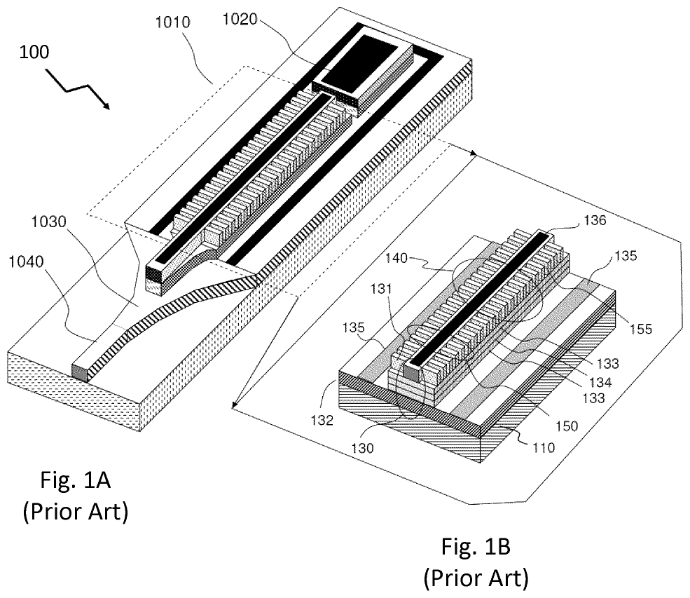

FIG. 1A and FIG. 1B show schematic views of an example of a LC SEG DFB laser 100, as disclosed by Watson et al. in U.S. Pat. No. 7,796,656. FIG. 1A shows the LC SEG DFB laser 1010 integrated with a rear facet power monitor (photo-diode detector) 1020 and a vertical mode transition waveguide 1030 to couple the laser output to a passive waveguide 1040 of a photonic integrated circuit. FIG. 1B shows an enlarged schematic diagram the LC SEG DFB laser of FIG. 1A. The laser p-i-n structure 130 is formed on a semi-insulating substrate 110 and comprises p-contact layer 132 and n-contact layer 131, upper and lower separate confinement heterostructure (SCH) layers 133, and MQW active gain region 134. The laser mesa 140 is processed by etching from the top surface of n-contact layer 131 to the p-contact layer 132. Contacts 135 and 136 are provided on top of the mesa and each side of the mesa. The SEG 150 is formed by a pair of periodic sequences of trenches 155 etched on either side of the n-contact layer 131, leaving a central unetched region (ridge) with periodic lateral ribs.

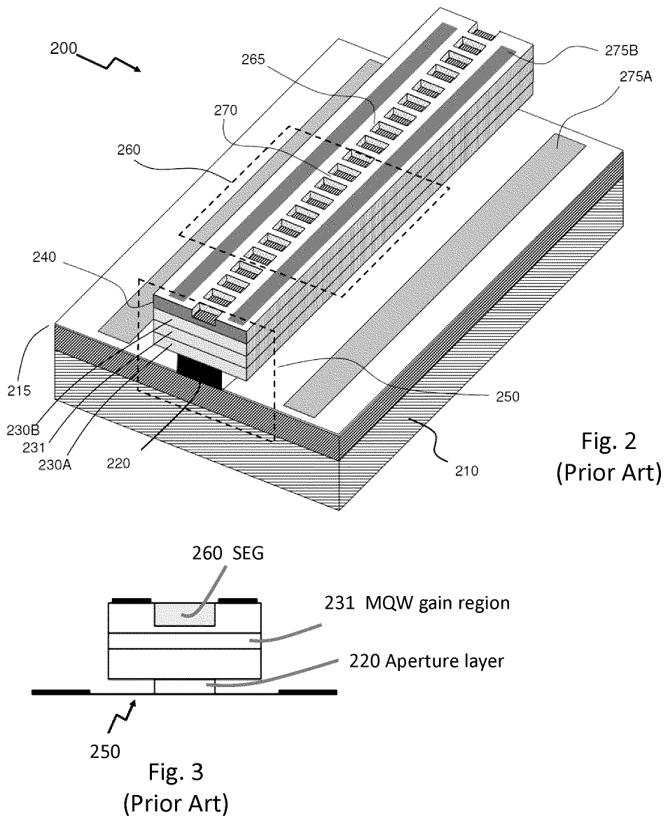

FIG. 2 shows a schematic view of an example of a VC SEG DFB laser 200, as disclosed by Watson et al. in United States patent publication no. US2012/0101583 comprising a substrate 210, lower contact/cladding layers 215, MQW active gain region 231 between upper and lower SCH layers 230A and 230B, upper contact/cladding layers 240, lower contacts 275A and upper contacts 275B. The SEG 260 comprises a set of etched trenches defining grating teeth 270. FIG. 3 is a schematic cross-sectional view to show the mesa structure 250 of the VC SEG DFB laser of FIG. 2, wherein the aperture layer 220, underlying the MQW gain region 231 is laterally undercut, so that the sidewall of the mesa has a profile that provides lateral confinement of current injection and lateral confinement of the fundamental optical mode.

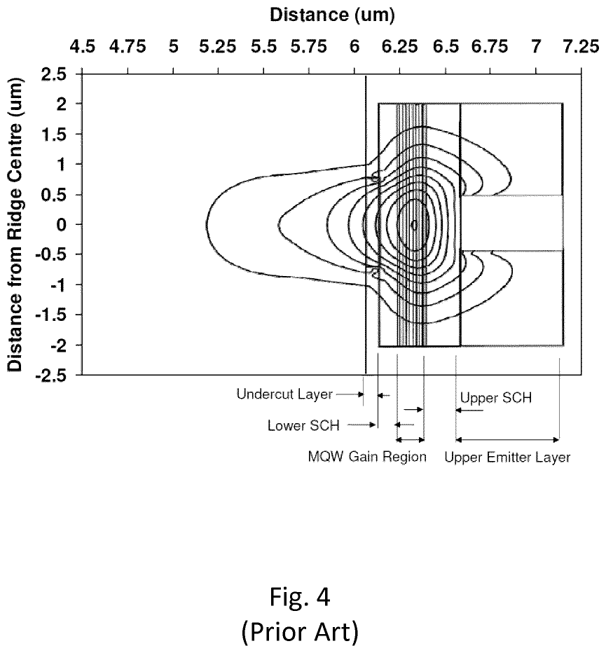

FIG. 4 shows a schematic diagram to illustrate the layer structure of the VC SEG DFB laser of FIG. 3, with contour lines for a two-dimensional profile of the mode pattern of the fundamental guided mode.

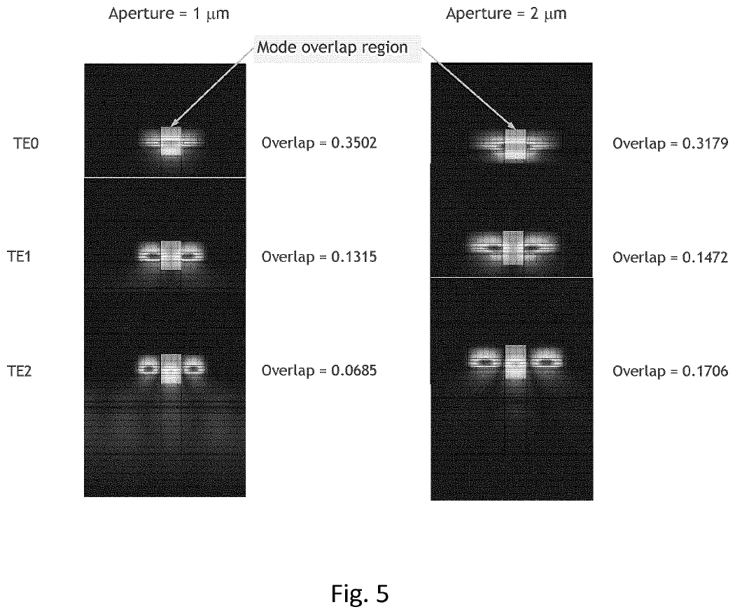

FIG. 5 show schematic diagrams illustrating results of modelling of modal intensity patterns for each of the TE0, TE1 and TE2 modes for examples of VC SEG DFB laser structures of embodiments having a 1 μm aperture and a 2 μm aperture, to illustrate the mode overlap region of the TE0, TE1 and TE2 modes. In each case, it is apparent that there is a region about 1 μm to 2 μm wide, where there is a high differential overlap between the TE0 mode and the TE1 and TE2 modes.

VC SEG DFB lasers may be coupled with transition waveguides, mode converters, and/or spot size converters to reduce higher order mode effects, e.g. to suppress TE1 and TE2 modes, for reliable operation at ≥2.5 Gb/s. For example, VC SEG DFB laser structures with etched rear reflectors may be structured to be compatible with monolithically integrated multi-guide vertical integration.

However, operation under some conditions, e.g. without transition waveguides and spot size converters, may result in unacceptable multi-transverse mode operation. For some applications, it is desirable to operate this type of VC SEG DFB laser without transition waveguides and spot size converters. Thus, there is a need for alternative solutions to suppress or reduce higher order mode effects, particularly for operation at ≥10 Gb/s.

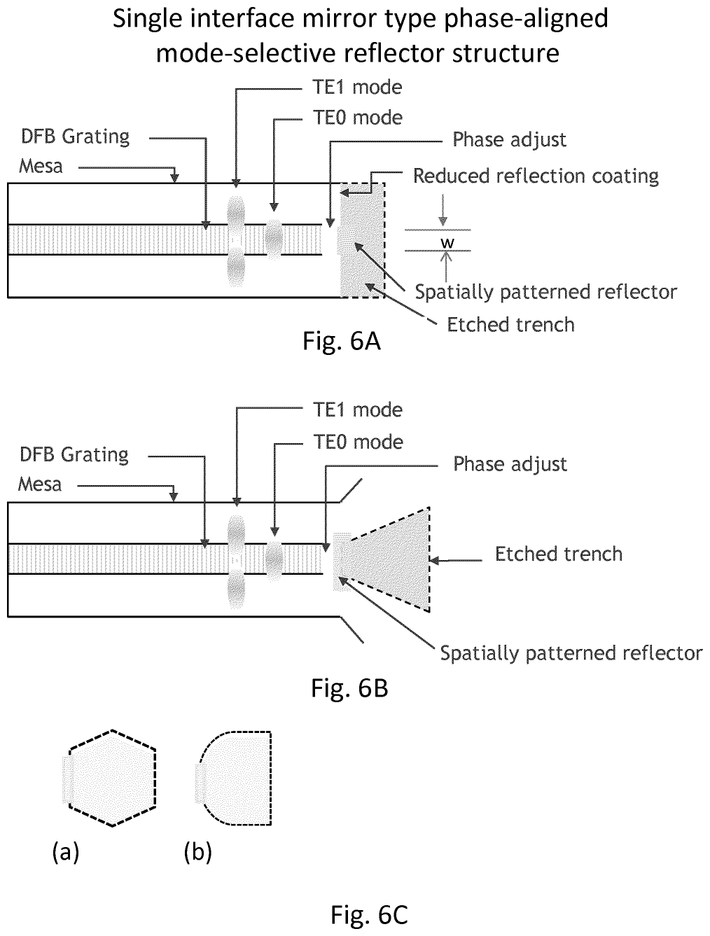

FIG. 6A is a schematic diagram of a device structure comprising a VC SEG DFB laser with a phase-aligned mode-selective reflector of a first embodiment, comprising a structured reflector in the form of a single interface mirror structure. As illustrated schematically, the laser mesa comprises a DFB SEG etched along the length of the mesa, e.g. similar to that shown in FIG. 2. The back-facet of the laser structure is formed by etching a trench, which in this embodiment it is a simple rectangular trench. One wall of the trench that forms the back-facet of the laser waveguide is spaced a predetermined distance from the grating, e.g. a multiple of λ/4, to provide a phase-adjust region, and a spatially patterned reflector is provided on the back-facet. The spatially patterned back reflector is configured to selectively reflect the TE0 mode, e.g. formed as a thin stripe reflector having dimensions which optimize reflection of the TE0 mode relative to the higher modes. Other areas of the back-facet are coated with a reduced reflection coating. This structure provides higher feedback of the fundamental mode TE0 as compared to the higher order transverse modes. For example, as illustrated schematically, the lateral dimensions (height in x direction and width in y direction) of the spatially patterned reflector are selected to provide higher feedback for the fundamental mode (along the optical axis −z direction) versus the TE1 and other higher modes. For example, since the TE1 mode extends laterally of the spatially patterned reflector, it interacts with the reduced reflection coating, e.g. a dielectric layer of an appropriate refractive index and thickness, which provides reduced feedback relative to the TE0 mode. The spatially patterned reflector is provided by a reflective facet coating that has an appropriate refractive index and thickness to provide high reflectivity of the TE0 mode. This reflective coating may be a metal facet coating such as a gold (Au) coating, or a dielectric coating such as silicon nitride (Si₃N₄) or silicon oxy-nitride (SiₓO_{y}N_{z}), or a combination of a metal layer and dielectric layer having a suitable refractive index to provide the required reflectivity.

FIG. 6B is a schematic diagram of a device structure comprising a VC SEG DFB laser with a phased aligned mode-selective reflector of a second embodiment. In this embodiment, the laser device structure comprises a single interface mirror structure in which the etched trench has a trapezoidal shape. The trapezoidal trench increases in width from the back-facet of the laser waveguide, and as illustrated schematically, the mesa also increases in width each side of the trench. Like the device structure of first embodiment, the narrower sidewall of the trapezoidal trench that forms the back facet of the laser diode has lateral dimensions (x, y) and a coating of a high reflectivity material which provides higher feedback for the fundamental mode TE0 relative to higher order modes.

In other embodiments, the etched trench providing the back-facet reflector may have other geometric forms. The etched trenches for the mirror structures of FIGS. 6A and 6B are shown with flat surfaces and sharp corners, but alternatively corners may be rounded, or sidewalls may be curved. For example, as illustrated by a few examples in FIG. 6C, (a) and (b), the lateral sidewalls of a trapezoidal trench may be curved (b), or the trench may have hexagonal shape (a), or other suitable geometric forms.

Suitable geometric forms and dimensions of the back-facet reflector are determined by optical modelling, based on parameters such as, the refractive indexes of the III-V materials of the laser mesa and the metal and/or dielectric facet coating materials (e.g. gold, silicon nitride, silicon oxynitride, et al.), lateral x-y dimensions of the laser aperture, layer thicknesses of facet coatings. It may be preferable that the spatially patterned reflector is formed by a coating of a dielectric material, rather than a metal reflector. If a metal reflector is used, plasmonic interactions may need to be considered.

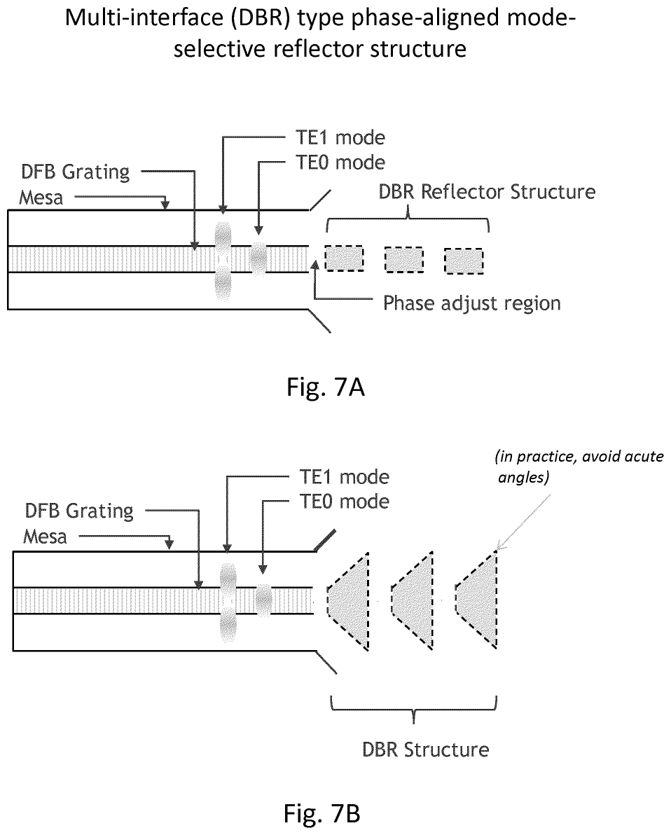

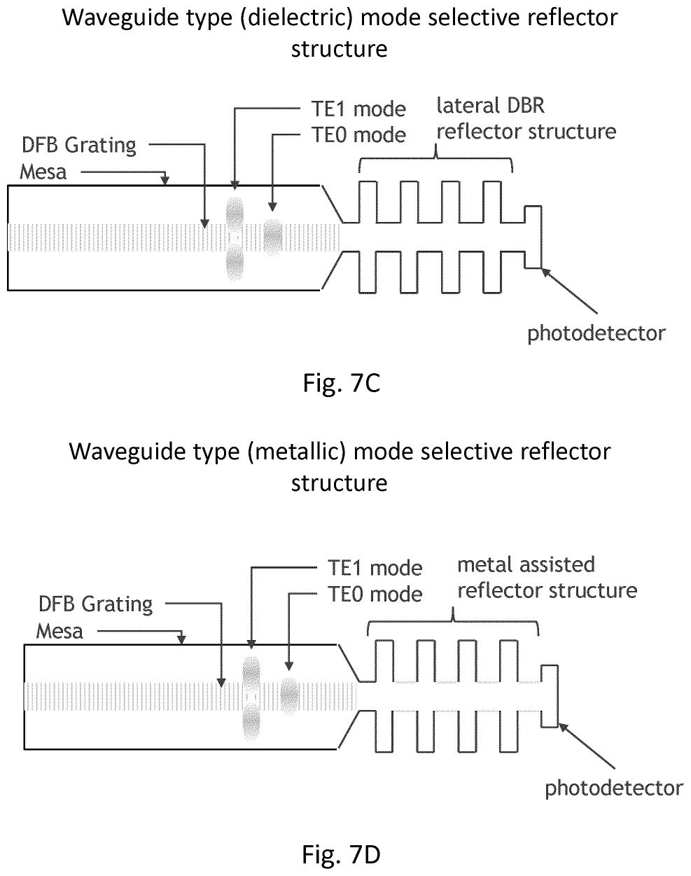

FIG. 7A is a schematic diagram of a device structure comprising a VC SEG DFB laser with a phase-aligned mode-selective reflector of a third embodiment comprising a multi-interface (DBR) type structure. In this structure, a spatially patterned back-facet reflector coating is replaced with a distributed Bragg reflector structure (DBR structure), which comprises a series of etched trenches defining a multi-interface reflector. In this embodiment, the etched trenches are rectangular trenches. This structure also includes a phase-adjust region between the DFB grating teeth of the laser and the DBR structure.

FIG. 7B is a schematic diagram of a device structure comprising a VC SEG DFB laser with a phase-aligned mode-selective reflector of a fourth embodiment comprising a multi-interface (DBR) type structure, wherein the etched trenches defining the multi-interface reflector are a series of trapezoidal trenches, separated from the DFB grating teeth of the laser by a phase-adjust region. In variants of this embodiment, the trapezoidal trenches may have curved sidewalls, and other geometric forms of trenches with flat or curved sidewalls may be used, as appropriate. As noted in FIG. 7B, in practice the trenches may be shaped to to avoid acute angles at the corners.

For each of the structures shown in FIGS. 7A and 7B, the dimensions and coating materials of the multi-interface DBR structure are configured to provide higher feedback of the fundamental TE0 mode relative to higher order transverse modes, e.g. TE1, TE2, etc.

The mode selective filter may comprise laterally defined features. For example, FIG. 7C is a schematic diagram of a device structure comprising a VC SEG DFB laser with a phased aligned mode-selective reflector of a fifth embodiment comprising a waveguide type (dielectric) lateral DBR structure; and FIG. 7D is a schematic diagram of a device structure comprising a VC SEG DFB laser with a phased aligned mode-selective reflector of a sixth embodiment comprising a waveguide type (metallic) lateral DBR type structure.

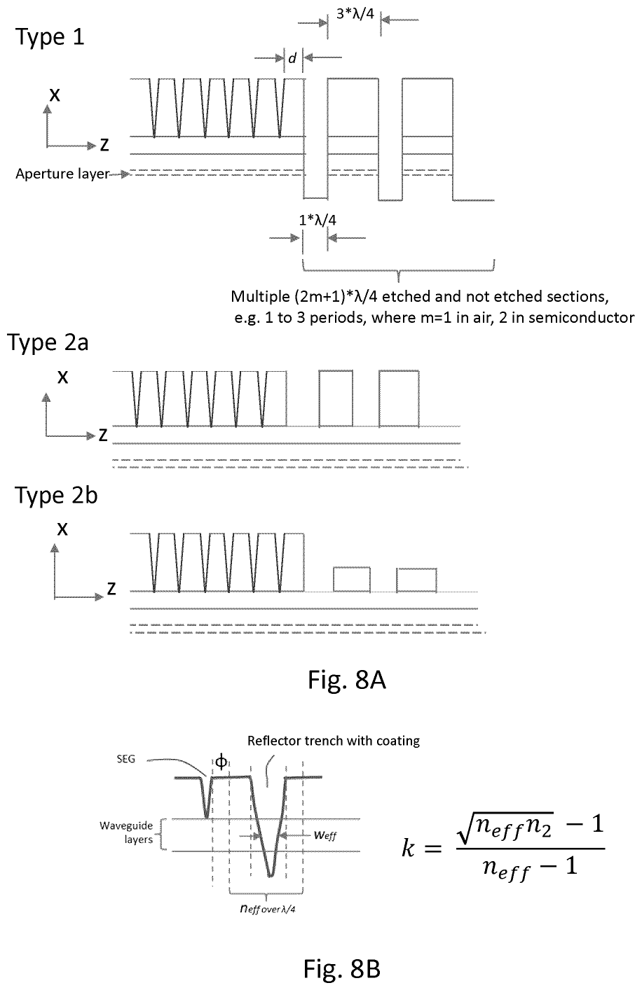

FIG. 8A shows schematic cross-sectional views of some variants of the device structures shown in FIGS. 7A and 7B comprising different options for etching of the SEG and DBR structure. In the type 1 structure, the DBR trenches are etched deeply, through all layers of the mesa structure, to below the aperture layer. For example, the etched trenches of the DBR structure have a width in the z-direction of 1*λ/4 and the unetched portions of the DBR structure have a width in the z-direction of 3*λ/4. After etching, the sidewalls of the DBR trenches are coated with a dielectric coating to provide the required reflectivity (see FIG. 8B). In the type 2a structure the DBR trenches are etched to the same depth as the trenches defining the DFB grating teeth. In the type 2b structure, the top part of the DBR features are also removed by etching to provide DBR features of reduced height in the x-direction.

After coating, in cross-section, the etched trenches may taper in width, e.g. as shown schematically in FIG. 8B, which shows part of the SEG, i.e. one etched trench, an etched trench of the back-facet reflector, and the phase shift region ϕ. To provide the required reflectivity k, the dimensions of the trench (etched portions) and unetched portions of the DBR structure, and the refractive index of the coating are selected to provide a required effective refractive index n_{eff} over a width of <<λ, e.g. λ/4, i.e. for an effective width w_{eff} of the trench along the axis of propagation (i.e. z-direction through the active gain region) as illustrated schematically in FIG. 8B.

For some applications, it may be desirable to select a mode other than the TE0 mode. In alternative embodiments, not illustrated, the selected mode is e.g. a first order TE1 mode and the spatially patterned reflector provides higher feedback of the TE1 mode relative to other modes, e.g. for lateral coupling to a waveguide.

In fabrication of the device structures described above, phase alignment of the SEG DFB grating teeth and the back facet reflector structure is an important consideration, whether this is a single interface reflector, e.g. as shown in FIGS. 6A and 6B, or a multi-interface DBR, e.g. as shown in FIGS. 7A and 7B, and variants thereof. Thus, as illustrated schematically in FIGS. 6A and 6B and FIGS. 7A and 7B, each of these structures includes a phase-adjust region (labelled as ϕ in FIG. 8B) between the SEG DFB grating teeth of the laser waveguide and the reflector structure.

To define the reflector structure with the required phase-adjust region, a suitable fabrication process is needed. The fabrication process must provide precise alignment for any sort of etched feature which need precise positioning relative to other etched features, such as aligning single interface reflectors or a multi-interface DBR type structure to the DFB grating with precise optical phase control. To provide phase-aligned laser reflectors, additional features defining the phase-aligned laser reflectors are included on the same mask that is used to define the DFB laser grating. This process also provided the ability to differentially mask regions to adjust etch depths of various features independently, e.g. for some different types of structures as shown schematically in the various views in FIGS. 6A to 6C, 7A to 7D and 8A and 8B.

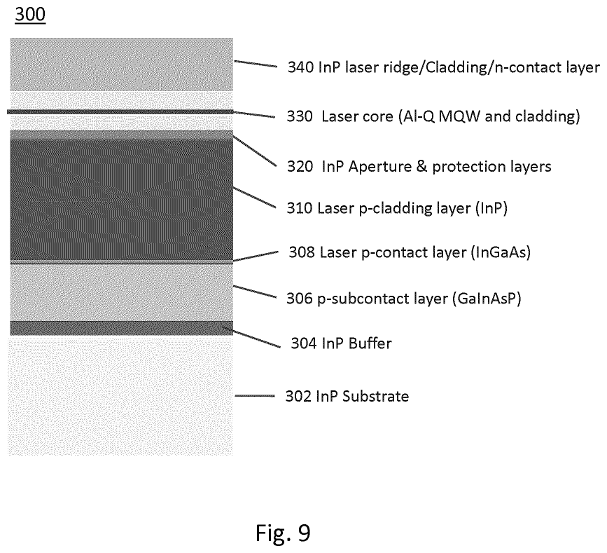

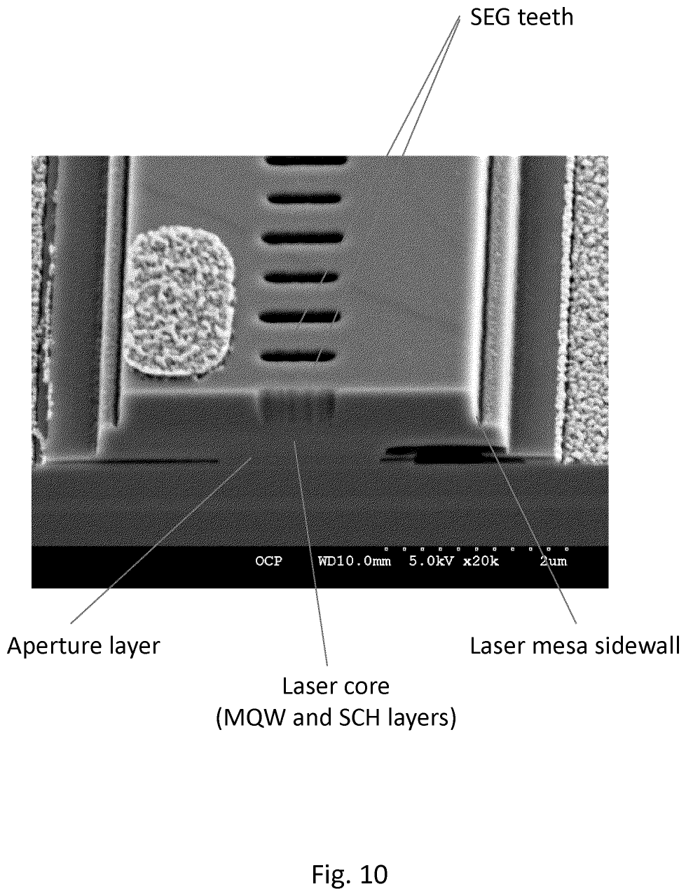

An example of an epitaxial layer structure (epi-layer stack) 300 for a fabrication of a device comprising a VC SEG DFB laser and structured reflector of an exemplary embodiment is shown schematically in FIG. 9. The epi-layer stack 300 is grown on an EJ-oriented semi-insulating (SI) InP substrate 302, and comprises a buffer layer 304 of InP, a p-subcontact layer 306, a p-contact layer 309, a p-cladding layer 310, current aperture layer and protection layers 320, a laser core 330 comprising an active MQW gain region and SCH cladding layers, and n-cladding and n-contact layers 340. Materials of an indium phosphide based materials system include, e.g. InP, InGaAs, InGaAsP (P-based quaternary (Q) layers), InAlAs (Al-based ternary (T) layers) and InAlGaAs (Al-based Q layers). It will be appreciated that the epitaxial layer structure of FIG. 9 is given by way of example only, and in practice layer compositions and layer thicknesses are selected as appropriate for a particular laser design and performance requirements. It will also be apparent that in the drawings, schematic representations of layer thicknesses and other dimensions are not to scale. As an example, FIG. 10 shows an SEM image of a cross-section of a laser mesa, showing the form and relative dimensions of a laser mesa structure with SEG. As described with reference to FIG. 2, the laser mesa is formed by etching from the top surface of the epitaxial layer stack to the p-contact layer. The aperture layer is undercut to provide lateral confinement of current injection and lateral confinement of the fundamental optical mode.

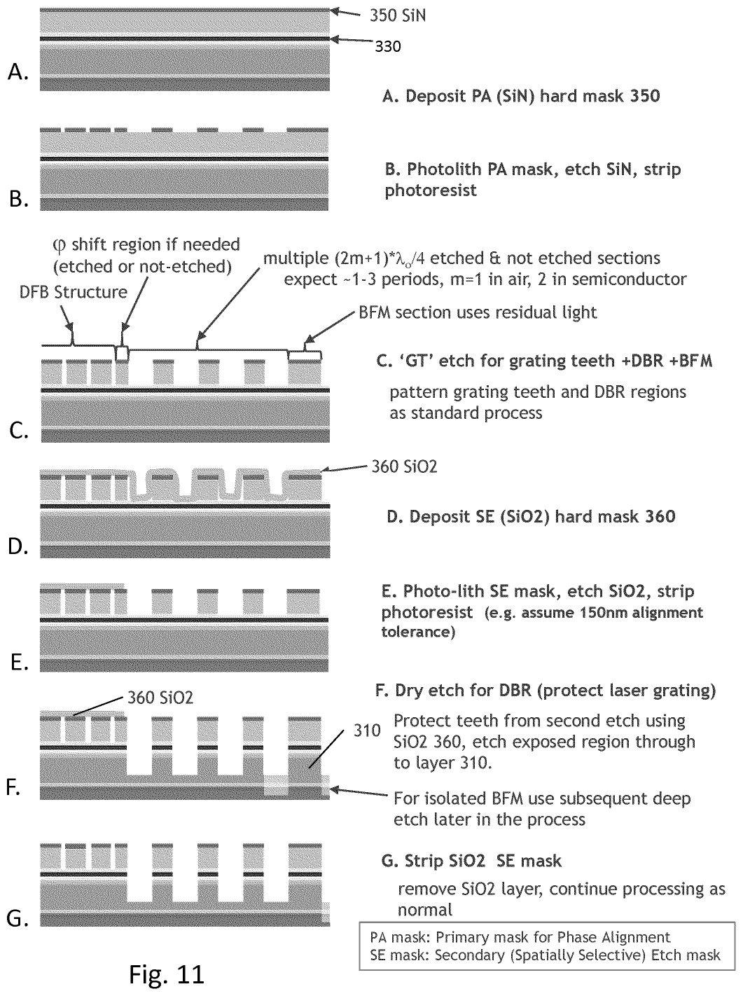

In a process for fabrication of the VC SEG DFB laser comprising a DBR reflector according to the embodiments shown in FIG. 7A or FIG. 7B, a wafer is provided with an epitaxial layer structure, e.g. as described with reference to FIG. 9. The epitaxial layer structure, and layer compositions and thicknesses represented schematically in FIG. 9 are provided by way of example only, to assist in understanding steps the fabrication process illustrated schematically in FIG. 11, which uses a similar colour representation to identify the layers of the device structure. FIG. 11 shows a series of schematic cross-sectional diagrams to illustrate steps A. to G. in a process for fabricating a laser structure comprising phase-aligned laser reflectors of an illustrative embodiment (process variant A with DBR and BFM). For example, the laser core 330 in FIG. 11 comprises the MQW active region (red/dark grey) and SCH layers (yellow/light grey).

Exemplary Fabrication Process

In the process illustrated schematically in FIG. 11, a phase alignment (PA) mask layer 350 is deposited, e.g. a layer of silicon nitride (FIG. 11, step A). The PA mask layer 350 may alternatively be referred to as the primary mask, and may comprise one or more layers of suitable materials. For example, the primary mask is patterned by standard photolithography steps, i.e. depositing and patterning a photo-resist layer, etching exposed areas of silicon nitride mask layer, and stripping of the photo-resist (FIG. 11, Step B). Thus, as illustrated schematically, the remaining silicon nitride layer masks areas defining the teeth of the SEG DFB structure of the laser waveguide, a phase shift region ϕ, and a plurality of regions defining the mode-selective structured DBR structure. A first etch step, which may be referred to as the grating etch or “GT etch” is performed to define the laser SEG DFB grating teeth, the DBR regions for the mode-selective DBR reflector structure, and a photo-diode structure for a back-facet monitoring. The GT etch process for patterning of the grating teeth and DBR region may be done by any suitable etch process, i.e. a standard grating etch process, or customized etch process. The GT etch removes material to define grating teeth in the upper layers, e.g. down to a surface of the upper SCH active layers indicated in yellow. It will be appreciated that a phase shift region ϕ may be formed as required (etched or unetched). Next, additional process steps are performed to define the DBR structure, while protecting the SEG DFB structure. To protect the SEG DFB structure, a selective etch (SE) hard mask, e.g. a layer silicon dioxide 360, is deposited overall. Another photolithography step is performed to pattern the SE hard mask, leaving the SEG structure protected, and exposing the areas for the DBR structure. For this photolithography step, it is assumed that there is an alignment tolerance, e.g. 15 nm. After etching the SE hard mask and stripping the photo-resist, another etch process is performed. For example, this is a dry etch to etch more deeply the DBR structure to define trenches of the DBR structure extending through the active layers into the underlying p-cladding layer 310. During this deeper etch, the SEG teeth are protected by remaining areas of the SE hard mask (SiO₂ layer) as illustrated schematically in (FIG. 11, Step F). If it is required to isolate the photo-diode detector, which is used for back-facet monitoring, a further deeper etch may be performed later in the process, i.e. to remove layers (e.g. p-cladding layer, p-contact layer and p-subcontact layers) each side of the photo-diode detector, down to the substrate, as indicated in FIG. 11, step F. After the deep etch process for the phase-aligned, mode-selective DBR structure, and after stripping remaining parts of the SE hard mask, subsequent processing proceeds as normal. Typically, the subsequent steps include etching to define the mesa sidewalls, etching of the aperture layer to define the aperture width, and formation of the upper and lower contacts by deposition of layers comprising dielectric (e.g. nitride), p-contact and n-contact metallization, and interconnect metallization and a surface passivation layer (e.g. nitride), and back-side wafer thinning.

Mask Design

Design of the phase-aligned (PA) mask for the DFB laser with a mode-selective single interface mirror or mode-selective DBR structure requires that the propagation constants for the desired mode are determined for each region, i.e. the unetched regions and the etched regions. For the unetched regions, any processes for shifting absorption or emission bands are considered. For etched regions, any dielectric coatings and filling materials are considered. The design of the DFB grating pattern includes any chirp defined by the grating period and/or lateral extent of the grating teeth. These parameters are used to define the desired un-etched/etched/un-etched pattern, including the distance from the last grating tooth to the first etched reflecting surface, dimensions of the etched regions and un-etched regions, e.g. dimensions for defining the mirror, DBR, waveguides, et al., while taking into account mask alignment accuracy for differentially etched areas, and residues left after subsequent processing. All elements are laid out on a single PA mask layer. At least one secondary etch (SE) mask is laid out to allow differential etching in some areas, while protecting other areas.

Process Variants

The process flow of the embodiment illustrated schematically in FIG. 11 is given by way of example only. It will be appreciated that the process flow of other embodiments may be adapted as required to define the SEG of the DFB laser, the phase shift region, the DBR structure, and other required features, such as a BFM detector. For example, the SEG DFB grating may be defined after forming the DBR structure.

The following are two examples of variants of the process.

Example Process Flow—Variant A
1. Deposit a primary (Phase Alignment (PA)) hard mask
2. Expose the PA mask layer pattern into the primary hard mask
3. Etch the shallowest etch first (i.e. first etch to first etch depth, e.g. for grating etch)
4. Deposit a secondary SE (selectively etched vs primary) hard mask
5. Photolithographically pattern the SE mask and selectively etch the secondary hard mask to allow etch access through the primary hard mask to the appropriate regions for additional etching
6. Etch the exposed regions
7. Strip the secondary SE hard mask
8. Optionally, fill the etched regions with a suitable dielectric material
9. Repeat steps 4-8 if required, e.g. to define features with different etch depths
10. Remove remaining secondary SE hard mask
11. Remove primary hard mask, if desired
12. Optionally, at this point or later in the overall laser fabrication sequence, process the trenches for desired fill material

Ideally the etched regions, e.g. the trenches of the reflector, are filled with air or other very low refractive index material. Low index minimizes the number of trenches for a given reflectivity. In practice, the trenches may be filled with a material such as BCB, which has a refractive index of ˜1.55-1.6. A hybrid fill may be used, e.g. a first layer of fill on the sidewalls and a bulk fill. The options chosen depend on process flow and available materials in the process.

Example Process Flow—Variant B

Similar to Variant A, except each etch is explicitly opened for the specific etch
1. Expose the PA mask layer pattern into the primary hard mask
2. Deposit secondary SE (selectively etched vs primary) hard mask
3. Photolithographically pattern the SE mask and selectively etch the secondary hard mask to allow etch access through the primary hard mask to the appropriate regions for additional etching
4. Etch the exposed regions
5. Strip the secondary SE hard mask
6. Repeat steps 3-5 as required
7. Remove remaining secondary hard mask
8. Remove primary hard mask, if desired.

In summary, a self-aligned process is used to form the device structure comprising a SEG DFB laser with a phase-aligned DBR structure which is configured to suppress higher order mode effects. The device structure is relatively simple to fabricate. A stepper mask is used to define both the surface etched grating and the DBR structure with phase-alignment. The first hard mask defines the fundamental pattern of interest, and at least one second mask, which is patterned differentially from the first hard mask, enables a sequence of etches of different etch depths to be performed independently to define the various elements of the required device structure. For example, a front facet could be added, and additional masks can be used to define other features. Typically, the shallowest etch is performed first. However, in variants of the method, the DBR structure may be defined first while the SEG grating mask is protected, and then the SEG grating is etched subsequently.

The resulting laser device structures of example embodiments provide at least one of good quality, low cost and high performance (high efficiency).

The process uses dielectric coatings for the DBR structure, which avoids use of metal reflectors such as gold, that have a complex refractive index, which would mean that plasmon effects would need to be taken into consideration.

The ability to use stepper mask photolithography to define features of the DFB grating and the phase-aligned mode-selective DBR structure provides increased flexibility relative to e-beam writing. The latter is a relatively expensive, and less accessible process.

The disclosed self-aligned fabrication process also allows for the grating to be made with chirp, either periodic chirp or chirp of the coupling coefficient. For chirp of the coupling coefficient, the width of the grating determines the coupling coefficient, and the process is scalable. The process also provides increased flexibility to include non-DFB laser features with SEG to make DFB lasers.

In the VC SEG DFB laser of the examples described above, the SEG is e.g. a third order grating. Although the grating period is limited by current lithographic technology, as technology improves in the future to facilitate definition of features of smaller dimension, the order of the SEG may be as low as first order. Smaller size grating teeth allows for many more teeth per unit length, with potential ability to provide more control of the refractive index created by the etched/not etched regions.

The process described in detail with reference to device structures of exemplary embodiments may also modified to be more generally applicable to structures comprising other forms of reflectors, such as echelle steps, sampled grating structures, photonic bandgap structures, aperiodic grating structures, apodized gratings, et al.

For example, lateral couplers or interference devices may be included, e.g. to position echelle grating teeth relative to the SEG grating of the DFB laser.

As another example, the mode-selective filter may comprise a first DBR reflector and a second DBR reflector, e.g. a first DBR reflector that acts as a broadband filter for the overall mode and a second DBR on the output to further select or tune a selected mode. Or, for example, a second DBR layer with multiple pitches in parallel (not sequence) with a waveguide selector (spatial demux) may be structured to choose which specific wavelength to couple, without requiring a taper layer.

Thus, more generally, the method may be extended for patterning a plurality of phase-aligned etched structures into a semiconductor substrate. For example, a method for patterning a plurality of phase-aligned etched structures into a semiconductor substrate comprises, alone or in combination with other process steps: providing the substrate with the desired structure; depositing a primary etch mask, comprising one or more layers of primary etching-mask materials; patterning the primary etch mask in a single high relative dimensional fidelity step.

Patterning the primary etch mask defines patterns for each of the plurality of phase-aligned etched structures, for subsequent etching of all desired phase-aligned patterns. That is, a single primary etch mask defines patterns for all etched structures which are to be phase-aligned. The method then proceeds, e.g. by at least the following steps:
providing additional patterned etch-protecting materials, e.g. area selective etch mask, over some regions of the primary mask;
etching the semiconductor areas exposed through the primary etch-mask to achieve a target result;
optionally, removing the etch protecting materials; and repeating these steps until all desired phase-aligned etched structures are completed.

If required, in one or more additional steps, some or all of the etched regions may be filled, e.g. with dielectric or other material.

After etching and completion of all desired phase-aligned etched structures, the primary etch-mask materials are removed, if required.

The primary etch masking layer defines the patterns for all desired phase-aligned structures in a single process step. The single high dimensional fidelity step could be single mask photolithography (e.g. the mask is typically made from an e-beam exposure), single write on-wafer via e-beam or focused ion beam, or other similar process capable of high fidelity relative positioning within the single application.

Then, a series of etch steps are performed, each using an area selective etch mask that exposes a part of the phase alignment primary etch mask, to allow one or more of the phase-aligned etch structures to be defined. For example, a first area selective etch mask is defined to expose a first area of the primary etch mask, and leave other areas protect, and then a first etch is performed to a required etch depth, e.g. a first etch depth through the exposed first area of the primary etch mask. If required, the first area selective etch mask is removed. Then, these process steps are repeated with a second area selective etch mask and a second etch to a second depth, and if required an nth area selective etch mask and nth etch to an nth etch depth for n≥3, until etched and not-etched regions are defined for all the phase-aligned device structures. As mentioned above, optionally, and if required, after each etch, or after completion of all etches, some or all of the etched regions may be filled, e.g., with a suitable dielectric material.

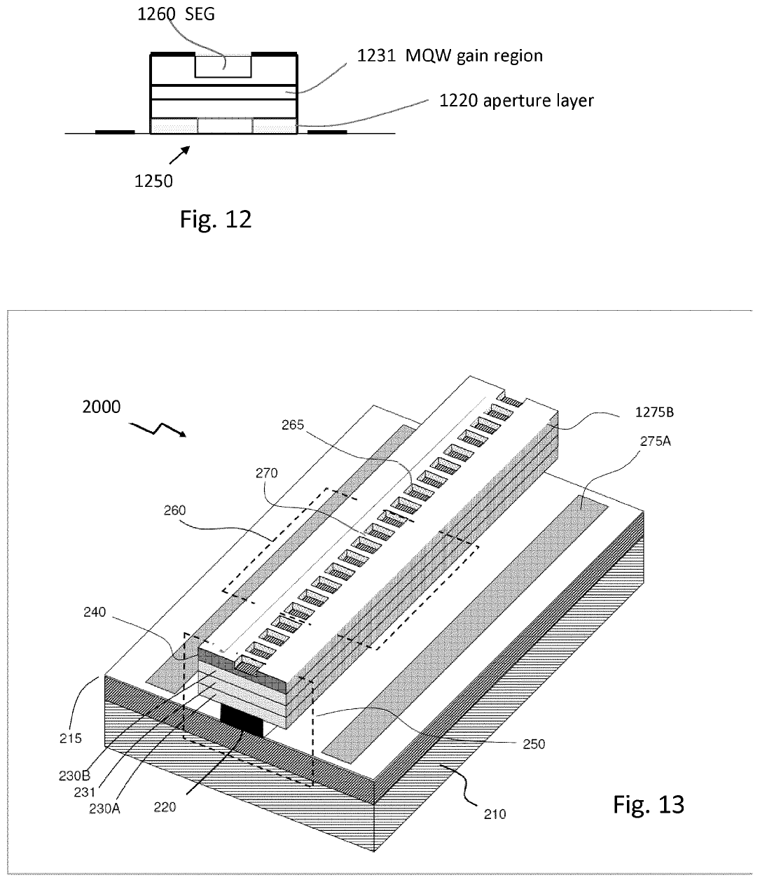

A schematic cross-sectional view of the mesa structure 1250 of a VC SEG DFB laser of another embodiment is shown in FIG. 12, comprises a MQW gain region 1231 and SEG 1260, similar to corresponding elements shown in FIG. 3. In this embodiment, the aperture layer 1220 is not laterally undercut or etched as shown in FIG. 3; instead the aperture is formed by a process such as ion implantation or chemical processing of an aperture layer, to modify the structure and composition of the aperture layer 1220 to form the aperture which provides lateral confinement of the current injection and lateral confinement of the optical mode. Since the aperture design of a standard ridge waveguide laser typically provides a 1 μm active region, undercutting the aperture layer to define the aperture width results in a potential area of structural weakness, i.e. excessive torque can break off the laser mesa. Thus, providing an aperture layer 1220 as illustrated in FIG. 12, or a similar aperture layer located closer to the top of the mesa may result in a more robust structure, or be beneficial for some applications.

A schematic diagram of a VC SEG DFB laser 2000 of yet another embodiment is shown in FIG. 13. In this embodiment, compared to the device structure shown in FIG. 2, corresponding parts are labelled with the same reference numerals. This device structure differs from that shown in FIG. 2 in a metal layer 1275B is provided on a top surface of the mesa and patterned to form an etch mask for the SEG. That is, a layer of conductive metal that forms at least part of the top contact for the laser may be extended to provide the etch mask for at least the SEG grating. Thus, the conductive layer 1275B extends across the grating teeth. The resulting top contact structure provides more improved ohmic placement for current flow through the active region.

In the example embodiments described in detail above, a VC SEG DFB laser comprises a phase-aligned mode-selective filter, which provides higher feedback of a fundamental mode, i.e. TE0 compared to other mode orders. In other embodiments, the phase-alignment region may be omitted and/or the detector for back-facet monitoring may be omitted from the VC SEG DFB laser. The method of fabrication is modified accordingly to omit these features.

In another embodiment, a SEG DFB laser comprises a mode-selective DBR back facet reflector, which in fabrication is defined by a first phase-aligned etch, and a non-mode selective, single interface front facet, which in fabrication is defined by a second a phase-aligned etch.

While laser device structures including a mode-selective filter comprising structured reflectors providing higher feedback to a selected mode, and a phase-alignment structure have been described with particular applicability to VC SEG DFB lasers, these features may also be applicable, independently or in combination, to other types of laser diodes.

For example, in semiconductor devices comprising laser diodes other embodiments a mode selective filter may be advantageous for multi-mode laser cavities, including Fabry-Perot (FP), DFB and DBR laser cavities, and may include spatially patterned reflectors fabricated from dielectric and/or metal layers.

In other embodiments, a phase alignment element may be advantageous for single longitudinal mode laser diodes (not FP laser diodes) with mode management structures such as DFB and DBR laser cavities, with either single mode or multi-mode cavities. The latter may include mode selective filters comprising spatially patterned reflectors comprising dielectric and/or metal layers. Inclusion of a detector for back-facet power monitoring is advantageous for embodiments comprising laser cavities supporting a single transverse mode, and multi-transverse mode laser cavities (i.e. any of FP, DFB and DBR laser cavities), and power monitoring benefits from dielectric reflectors.

While specific embodiments of semiconductor structures comprising laser diodes have been described with features comprising one or more of mode-selective filters, comprising single facet or multi-facet reflectors; phase-alignment elements; and detectors for back-facet monitoring, these embodiments are described by way of example only. Other embodiments of FP, DFB and DBR laser diodes comprising feasible combinations of these features, may provide one or more advantages over prior art device structures.

Although embodiments of the invention have been described and illustrated in detail, it is to be clearly understood that the same is by way of illustration and example only and not to be taken by way of limitation, the scope of the present invention being limited only by the appended claims.

1-19. (canceled)

20. A device structure comprising a distributed feedback (DFB) laser diode comprising a surface-etched grating (SEG) supporting a fundamental optical mode, the DFB laser diode having etched front and back facets, wherein the back facet comprises a mode-selective structured reflector providing higher feedback of a fundamental mode TE0 compared to higher order modes.

21. The device structure of claim 20, wherein the mode-selective structured reflector is a phase-aligned mode-selective reflector structure spaced from teeth of the SEG by a phase-alignment region.

22. The device structure of claim 20, wherein the mode-selective structured reflector comprises a single interface reflector on the back-facet comprising a spatially patterned reflective coating on said back-facet that provides said higher feedback of the fundamental mode TE0 relative to higher order modes.

23. The device structure of claim 22, wherein the mode-selective reflector structure is a phase-aligned reflector structure wherein the single interface reflector comprises an etched trench defining the back-facet, and the back-facet is spaced from teeth of the SEG by a phase-alignment region.

24. The device structure of claim 23, wherein a sidewall of the trench defines the back-facet and the spatially patterned reflective coating comprises a high reflectivity coating in a region aligned to the TE0 mode and a lower reflectivity coating on other parts of the sidewall.

25. The device structure of claim 24, wherein the trench is one of: a rectangular trench, a trapezoidal trench, hexagonal trench, and trenches of other suitable geometric forms including curved forms.

26. The device structure of claim 20, wherein the mode-selective structured reflector comprises a multi-interface distributed Bragg reflector (DBR) structure defined by a plurality of etched and un-etched regions defining a series of trenches aligned to the back-facet, sidewalls of said trenches of the DBR structure comprising a dielectric coating that provides said higher feedback of the fundamental mode TE0 relative to higher order modes.

27. The device structure of claim 26, wherein the DBR structure is a phase-aligned DBR structure spaced from teeth of the SEG by a phase-alignment region.

28. The device structure of claim 27, wherein the trenches have a geometric form which is one of a rectangular trench, a trapezoidal trench, a hexagonal trench, and trenches of other suitable geometric forms including curved forms.

29. The device structure of claim 26, wherein the etched and unetched regions comprise a plurality of (2m+1)*λ/4 etched and not-etched sections, comprising 1 to 3 periods, where m=1 in air or other low index material, and 2 in semiconductor or other high index material.

30. The device structure of claim 20, further comprising a detector for back-facet power monitoring.

31. The device structure of claim 26, wherein the SEG DFB laser is a VC SEG DFB laser fabricated from an epitaxial layer structure comprising a plurality of semiconductor layers grown on a semiconductor substrate;
the plurality of semiconductor layers comprising a first contact layer, a first cladding layer, a first separate confinement heterostructure, a multi-quantum well active gain region, a second separate confinement heterostructure, and a second cladding layer and a second contact layer;
a surface-etched grating (SEG) comprising a set of periodic trenches defined along a top surface of a mesa etched through the plurality of semiconductor layers, the SEG forming a vertically coupled waveguide Bragg grating supporting a fundamental optical mode,
wherein the first and second separate confinement heterostructures provide vertical optical confinement of the fundamental optical mode; and
at least one layer of the plurality of semiconductor layers forms an aperture layer that provides lateral optical confinement of the fundamental optical mode and lateral confinement of current injection; and
wherein etched regions of the DBR structure are etched through at least upper layers of said plurality of semiconductor layers.

32. The device structure of claim 31, wherein etched regions of the DBR structure are etched through layers of said plurality of semiconductor layers to the first cladding layer.

33. A method of fabricating a device structure comprising a SEG DFB laser and a phase-aligned mode-selective reflector structure, comprising:
providing a substrate comprising an epitaxial layer structure for the SEG DFB laser;
depositing a primary etch mask layer comprising one of more layers of etch mask materials;
and patterning the primary etch mask layer in a single process step to define patterns of etch and not-etch regions for each of a plurality of phase-aligned structures, which comprise at least the SEG for the DFB laser, a phase-alignment region, and a mode-selective reflector structure; and
processing the plurality of phase-aligned etched structures by a sequence of area selective masking and etching steps.

34. The method of claim 33, comprising performing an initial etch to an initial etch depth to define initial parts of each of the plurality of phase-aligned etched structures.

35. The method of one of claim 33, comprising:
patterning a first area selective etch (SE) mask which exposes a first area of the primary etch mask comprising patterns for at least the SEG, phase alignment region and mode-selective reflector structure, and protects other areas of the primary etch mask;
performing a first etch to a first etch depth defining the SEG and defining first depth etched/not-etched regions for the phase-alignment region and the mode-selective reflector structure; and if required, removing the first area selective etch mask;
depositing and patterning a second area selective etch (SE) mask layer which protects the SEG and exposes areas of the primary etch mask comprising the phase-alignment region and the mode-selective reflector structure;
performing a second etch to a second etch depth defining second depth etched/not-etched features of the phase-alignment region and the mode-selective reflector structure; and
if required, removing the second area selective etch mask.

36. The method of claim 35, further comprising, for n≥3:
depositing and patterning an n^{th} selective etch (SE) mask layer; and
performing an n^{th} etch to a n^{th} etch depth further defining features of the phase-alignment region and the mode-selective reflector structure; and
if required, for n>3, repeating area selective masking and etching, until each of the plurality of phase-aligned etched structures for the SEG, the phase-alignment region and the mode-selective reflector structure, and any other phase-aligned etched structures are completed.

37. The method of claim 33, wherein the primary mask layer defines etch and not-etch regions for the mode-selective reflector comprising a trench for a single interface back facet reflector; and
after steps comprising the first etch step and at least a second etch defining the mode-selective reflector comprising the trench,
depositing a spatially patterned reflective coating on a sidewall of the trench defining the back-facet of the SEG DFB laser, the spatially patterned reflective coating comprising a first region of a high reflectivity coating that provides higher feedback to a fundamental TE0 mode relative to higher order modes of the SEG DFB laser, and other regions of the spatially patterned reflective coating having a lower reflectivity coating.

38. The method of claim 33, wherein the primary mask layer defines etch and not-etch regions for the mode-selective reflector comprising a series of trenches of a mode-selective DBR structure; and
after steps comprising the primary etch step and at least a first selective etch defining the mode-selective reflector comprising the series of trenches,
depositing a dielectric coating on sidewalls of the series of trenches to form a DBR structure that provides higher feedback to a fundamental TE0 mode relative to higher order modes of the SEG DFB laser.

39. The method of claim 33, wherein the primary mask layer further defines etch/not etch regions of a detector for back-facet power monitoring.

40. The method of claim 35, wherein the first area selective masking step and first etch defining the SEG is performed after the second etch forming the phase-alignment region and mode-selective reflector structure.

41-45. (canceled)
